(19) United States
(12) Patent Application Publication
(10) Pub. No.: US 2024/0072010 A1
(43) Pub. Date: Feb. 29, 2024

(54) PACKAGE

(71) Applicant: ROHM CO., LTD., Kyoto-shi (JP)

(72) Inventors: Yohei MORIYAMA, Kyoto (JP); Atsushi YAMAGUCHI, Kyoto (JP)

(21) Appl. No.: 18/504,850

(22) Filed: Nov. 8, 2023

Related U.S. Application Data
(63) Continuation of application No. PCT/JP2022/018467, filed on Apr. 21, 2022.

(30) Foreign Application Priority Data
May 13, 2021 (JP) 2021-081690

(51) Int. Cl. H01L 25/07; H01L 23/00; H01L 23/367; H01L 25/16

(52) U.S. Cl. CPC H01L 25/072; H01L 23/367; H01L 24/32; H01L 25/16; H01L 2224/32225; H01L 2224/32245; H01L 2924/1306

(57) ABSTRACT

A package includes: a first portion having defined therein a mounting region in which an electronic component is mounted; and a second portion connected to the first portion. An area of the second portion is larger than an area of the first portion in plain view viewed from the direction normal to a surface through which the first portion and the second portion are connected.

### CROSS REFERENCE TO RELATED APPLICATIONS AND INCORPORATION BY REFERENCE

This is a continuation application (CA) of PCT Application No. PCT/JP2022/018467, filed on Apr. 21, 2022, which claims priority to Japan Patent Application No. P2021-081690 filed on May 13, 2021 and is based upon and claims the benefit of priority from prior Japanese Patent Application No. P2021-081690 filed on May 13 2021 and PCT Application No. PCT/JP2022/018467, filed on Apr. 21, 2022; the entire contents of each of which are incorporated herein by reference.

### TECHNICAL FIELD

The embodiments herein relate to a package in which an electronic component is mounted.

### BACKGROUND

Electronic components are mounted in packages to be incorporated on circuit boards. Electronic components are electrically connected to peripheral components incorporated on circuit boards via wiring arranged on the circuit boards.

By using a material with high thermal conductivity for a package, heat generated by an electronic component can be efficiently emitted to outside of the package. To increase the performance of radiating heat generated by an electronic component, a package that is larger in size than the electronic component is used.

### BRIEF DESCRIPTION OF THE DRAWINGS

FIG. 1 is a schematic diagram showing the configuration of a package according to a first embodiment.

FIG. 2 is a schematic diagram showing the connection between an electronic component mounted in the package according to the first embodiment and wiring arranged on a wiring substrate.

FIG. 3 is a schematic diagram showing the configuration of a package of a comparative example.

FIG. 4 is a schematic diagram showing a heat diffusion region.

FIG. 5 is another schematic diagram showing a heat diffusion region.

FIG. 6 is a schematic diagram for explaining the size of the package according to the first embodiment.

FIG. 7 is a schematic diagram showing a model for explaining heat diffusion.

FIG. 8 is a schematic diagram showing the configuration of a package according to a modified example of the first embodiment.

FIG. 9 is a schematic diagram showing the configuration of a package according to a second embodiment.

FIG. 10 is a schematic diagram showing an example of the arrangement of columns of the package according to the second embodiment.

### DETAILED DESCRIPTION

Next, embodiments will be described with reference to the drawings. In descriptions of the drawings below, the same or similar parts are denoted by the same or similar reference numerals. It should be noted, however, that the drawings are schematic, and that the relationships between the thicknesses and the planar dimensions, the thickness ratios of each part, and the like are different from those in reality. In addition, it is needless to say that the drawings include portions in which the relationships and the ratios of the dimensions are different from each other.

Further, the following embodiments exemplify an apparatus and a method for embodying a technical idea, and do not specify the shape, structure, disposition, and the like of each component. In the embodiments, various modifications can be made within the scope of the claims.

### First Embodiment

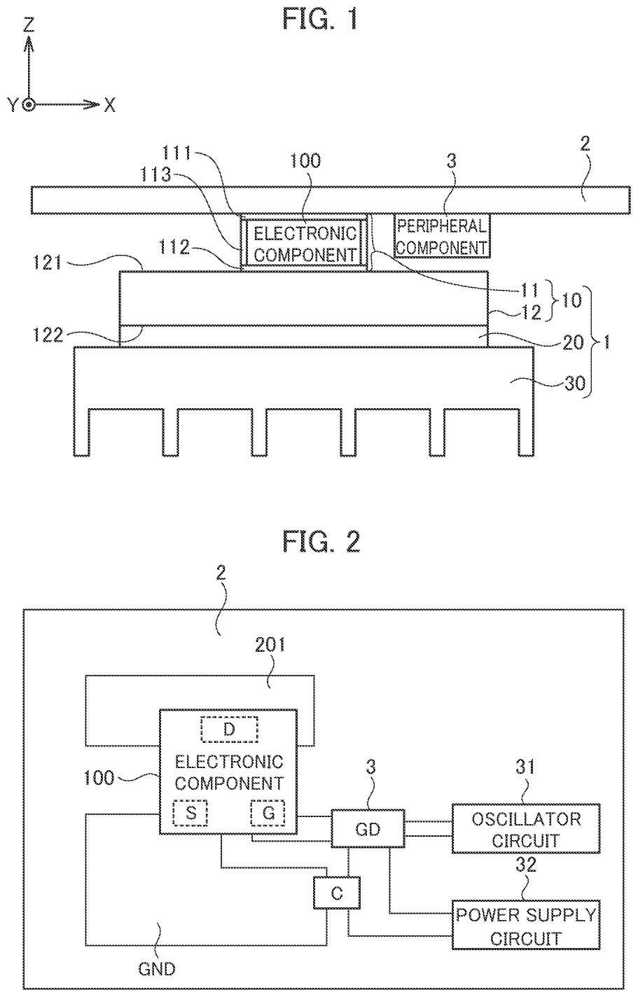

An electronic component 100 can be mounted in a package 1 according to a first embodiment, and the package 1 has a first portion 11 and a second portion 12 connected to the first portion 11 as shown in FIG. 1. The first portion 11 and the second portion 12 of the package 1 may be integrated. Hereinafter, the entire configuration in which the first portion 11 and the second portion 12 are connected is referred to as a mounting portion 10.

The electronic component 100 is a transistor or the like formed on a semiconductor substrate. For example, a transistor formed on a gallium nitride (GaN) substrate is mounted in the package 1, and the package 1 is incorporated on the surface of a wiring substrate 2.

A mounting region for mounting the electronic component 100 is defined inside the first portion 11. FIG. 1 shows a state in which the electronic component 100 is mounted in the mounting region inside the first portion 11. As shown in FIG. 1, the area of the second portion 12 is larger than that of the first portion 11 in plain view viewed from the direction normal to the surface through which the first portion 11 and the second portion 12 are connected (hereinafter simply referred to as “plain view”).

Hereinafter, an area in plain view is also simply referred to as an “area”. The direction normal to the surface through which the first portion 11 and the second portion 12 are connected is defined as the Z-axis direction. The plane perpendicular to the Z-axis direction is defined as the XY-plane, the left-right direction in the page space of FIG. 1 is defined as the X-axis direction, and the direction perpendicular to the page space is defined as the Y-axis direction.

As shown in FIG. 1, the package 1 is incorporated on the wiring substrate 2 with the first portion 11 facing the wiring substrate 2. The package 1 is configured to enable electrical connection between the electronic component 100 and wiring arranged on the wiring substrate 2. For example, the electronic component 100 and the wiring arranged on the wiring substrate 2 are electrically connected via a terminal (not shown) arranged in the package 1.

The first portion 11 has a first plate 111 and a second plate 112 which are arranged to be apart from and opposite from each other. The first plate 111 faces the wiring substrate 2. The second plate 112 is connected to the second portion 12. The electronic component 100 is mounted in a hollow portion between the first plate 111 and the second plate 112. For example, a mounting region is set on the surface of the second plate 112 facing the first plate 111, and the electronic component 100 is joined to the second plate 112.

Both surfaces of the second portion 12 are defined by a first surface 121 connected to the first portion 11 and a second surface 122 facing the first surface 121. The first surface 121 is thermally connected to the mounting region of the first portion 11. For example, the first surface 121 of the second portion 12 is thermally connected to the mounting region by joining the electronic component 100 to the first portion 11 using a thermally conductive material. For example, the electronic component 100 may be soldered to the mounting region of the first portion 11 to thermally connect the first surface 121 to the mounting region. Alternatively, the electronic component 100 may be joined to the mounting region of the first portion 11 by using a thermally conductive adhesive.

By forming the mounting portion 10 using a material with good thermal conductivity, heat generated by the electronic component 100 can be efficiently radiated to outside of the mounting portion 10 from the second surface 122 of the second portion 12. Therefore, a metal material may be used to form the mounting portion 10. For example, copper with high thermal conductivity may be used as a material for forming the mounting portion 10. When copper is used as the material for forming the mounting portion 10, the thermal conductivity of the mounting portion 10 is about 400 W/(m*K). Alternatively, lightweight aluminum may be used as the material for forming the mounting portion 10. In the package 1, in plain view, since the area of the second portion 12 is larger than that of the first portion 11 including the mounting region, even if the thermal conductivity of the wiring substrate 2 is low, heat generated by the electronic component 100 can be effectively radiated from the second portion 12.

As shown in FIG. 1, the vicinity of the mounting region is surrounded by the first plate 111, the second plate 112, and side plates 113 connecting the first plate 111 and the second plate 112 of the first portion 11. Due to the electronic component 100 also contacting the side plates 113 of the first portion 11, the heat generated by the electronic component 100 propagates more efficiently from the first portion 11 to the second portion 12 than when the electronic component 100 contacts only the second plate 112.

The first portion 11 is arranged in the center of the first surface 121 of the second portion 12, for example. By arranging the first portion 11 in the center of the first surface 121, the heat generated by the electronic component 100 propagates through the second portion 12 while being spread evenly, from the region of the first surface 121 contacting the first portion 11 toward the second surface 122. Due to the heat generated by the electronic component 100 being spread evenly, the entire second portion 12 can be used for heat propagation.

The electronic component 100 mounted in the package 1 is electrically connected to the wiring arranged on the wiring substrate 2 via, for example, a terminal (not shown) arranged on the surface of the first portion 11. A peripheral component 3 is, for example, a driving device for driving the electronic component 100 when the electronic component 100 is an active element such as a transistor. Alternatively, the peripheral component 3 is a passive component such as a chip capacitor or a resistive element added to the electronic component 100. For example, if the electronic component 100 is a transistor, the peripheral component 3 is a gate driver (GD) that drives the transistor.

FIG. 2 shows an example of connection between the electronic component 100 and the wiring arranged on the wiring substrate 2 when the electronic component 100 is a transistor having a drain electrode D, a source electrode S, and a gate electrode G. The drain electrode D of the electronic component 100 is electrically connected to drain wiring 201 arranged on the wiring substrate 2. The source electrode S of the electronic component 100 is electrically connected to ground wiring GND arranged on the wiring substrate 2. The gate electrode G of the electronic component 100 is electrically connected to the GD which is the peripheral component 3 via the wiring arranged on the wiring substrate 2. The GD is connected to an oscillator circuit 31 and a power supply circuit 32 which are arranged on the wiring substrate 2. Further, a capacitor C is connected between the ground wiring GND and wiring connecting the GD and the power supply circuit 32.

The mounting portion 10 has a mesa shape in which the first portion 11 protrudes from the second portion 12 in a side view viewed from the direction perpendicular to the surface through which the first portion 11 and the second portion 12 are connected. In the package 1 in which the first portion 11 faces the wiring substrate 2, the second portion 12 and the wiring substrate 2 are spaced apart by the thickness of the first portion 11 in the Z-axis direction (hereinafter simply referred to as “thickness”). Therefore, as shown in FIG. 1, the peripheral component 3 can be arranged between the second portion 12 and the wiring substrate 2. Therefore, according to the package 1, when the package 1 is arranged on the wiring substrate 2, it is possible to shorten the wiring on the wiring substrate 2 connecting the electronic component 100 and the peripheral component 3.

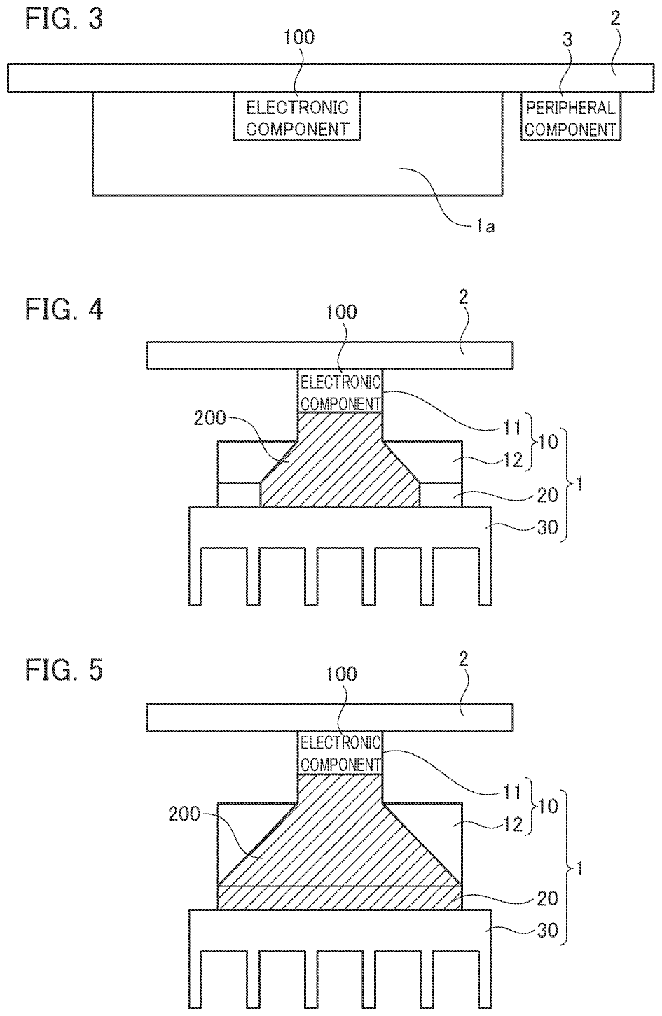

Meanwhile, as in a comparative example shown in FIG. 3, in a package 1a having a flat surface facing the wiring substrate 2, the peripheral component 3 needs to be arranged in a region outside the region in which the package 1a is arranged. This increases the length of the wiring on the wiring substrate 2 electrically connecting the electronic component 100 mounted in the package 1a and the peripheral component 3. If the wiring becomes long, the parasitic inductance of the wiring increases and the performance of the electronic component 100 decreases.

Meanwhile, in the package 1 in which the area of the first portion 11 is smaller than that of the second portion 12 in plain view, the peripheral component 3 can be arranged between the second portion 12 and the wiring substrate 2. Therefore, the wiring connecting the electronic component 100 mounted in the package 1 and the peripheral component 3 is shorter than the wiring connecting the electronic component 100 mounted in the package 1a and the peripheral component 3. Therefore, the package 1 can suppress an increase in the parasitic inductance of the wiring.

The package 1 shown in FIG. 1 has an insulating heat conduction sheet 20 arranged on the second surface 122 of the second portion 12. The heat conduction sheet 20 faces the first portion 11 with the second portion 12 therebetween. Further, the package 1 has a heat sink 30 which is arranged on the heat conduction sheet 20 and faces the second portion 12 with the heat conduction sheet 20 therebetween.

In the package 1, the heat generated by the electronic component 100 propagates to the heat sink 30 through the mounting portion 10 and the heat conduction sheet 20. The heat sink 30 emits the heat propagated from the heat conduction sheet 20 to outside of the package 1.

A sheet-like member with high thermal conductivity such as a resin sheet is used for the heat conduction sheet 20. The thermal conductivity of the heat conduction sheet 20 is, for example, about several W/(m*K). For example, a silicone sheet or the like is used for the heat conduction sheet 20. A material with high thermal conductivity such as metal is used as the material of the heat sink 30. For example, copper or aluminum is used for the material of the heat sink 30. The thermal conductivity of the heat sink 30 using aluminum is about 200 W/(m*K).

The larger the area of the heat conduction sheet in plain view, the higher the thermal conductivity of the package 1. However, if the second portion 12 is thin, as shown in FIG. 4, a heat diffusion region 200 shown with hatching only spreads to a partial region of the second surface 122 of the second portion 12. That is, even if the area of the heat conduction sheet is increased, if the heat diffusion region 200 in the second surface 122 is narrow, the effect of radiating the heat generated by the electronic component 100 is reduced.

Therefore, as shown in FIG. 5, it is preferable to set the thickness of the second portion 12 such that the heat diffusion region 200 in the second portion 12 is approximately the entire surface of the second surface 122. A condition for setting the thickness of the second portion 12 such that the heat diffusion region 200 is approximately the entire surface of the second surface 122 is hereinafter also referred to as a “setting condition”. If the thickness of the second portion 12 satisfies the setting condition, high thermal conductivity can be achieved in the package 1.

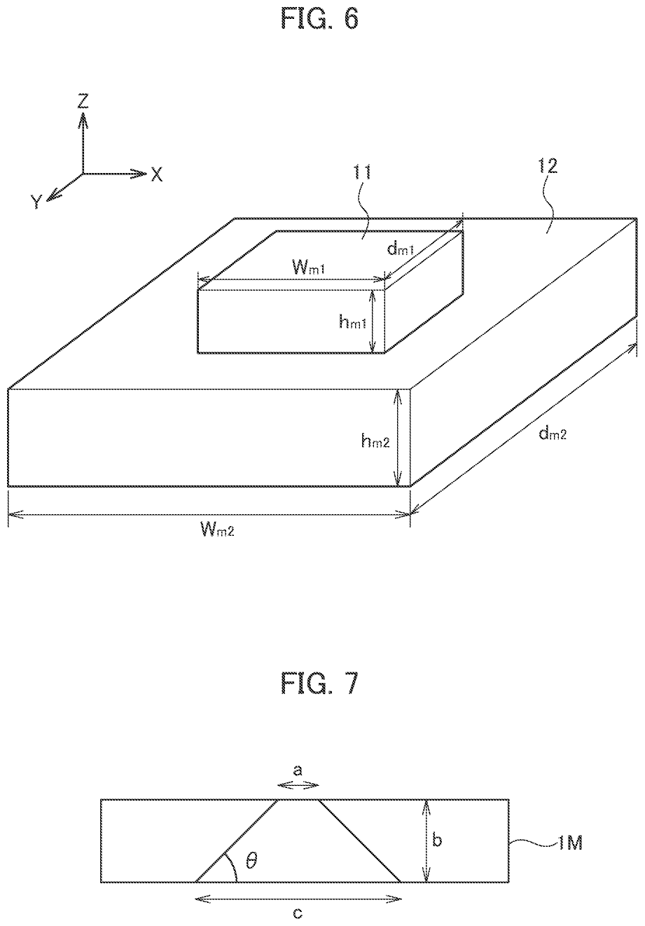

As the setting condition for achieving high thermal conductivity in the package 1, the size of the mounting portion 10 will be investigated below. Assuming that the first portion 11 and the second portion 12 have a parallelepiped shape, the size of the first portion 11 and the size of the second portion 12 are defined as shown in FIG. 6. Hereinafter, the length of the side in the X-axis direction is referred to as the “width”, the length of the side in the Y-axis direction is referred to as the “depth”, and the length of the side in the Z-axis direction is referred to as the “height”.

As shown in FIG. 6, the size of the first portion 11 is a width Wm1, a depth dm1, and a height hm1. The size of the second portion 12 is a width Wm2, a depth dm2, and a height hm2. The width Wm1, the depth dm1, and the height hm1 are larger than the width, depth, and height of the electronic component 100. Further, the height hm1 is larger than the height of the peripheral component 3.

A description will be given below regarding a case in which the size of the mounting portion 10 as the setting condition is determined based on an upper limit of a thermal resistance value of the heat conduction sheet 20. If the thermal conductivity of the heat conduction sheet 20 is λ(W/(m*K)), the height is hs(m), and the area is s(m²), the thermal resistance value R(K/W) of the heat conduction sheet 20 is represented by following formula (1).

R=hs/(λ*s) (1)

As shown in formula (1), the larger the area s, the smaller the thermal resistance value R.

Here, as shown in FIG. 7, it is assumed that heat is transferred from a range of the width a of the upper surface to a range of the width c of the lower side in a model 1M having the thickness b. When heat is transferred to the lower side by forming an angle θ (rad), the width c is represented by the following formula (2).

c=a+2b*cos θ/sin θ (2)

When heat is transferred from the first portion 11 to the second portion at an angle θ with respect to the second surface 122 of the second portion 12, from the formula (2), an area S2 of the heat diffusion region 200 in the second surface 122 of the second portion 12 is represented by the following formula (3).

S2=(wm1+2*hm2*cos θ/sin θ)*(dm1+2*hm2*cos θ/sin θ) (3)

From the above, the following formula (4) holds as the setting condition.

S2≥s=hs/(λ*R) (4)

From the formula (4), following formulas (5), (6), and (7) hold.

hm2≥(−D+E)/(4*S2) (5)

D=(Wm1+dm1) (6)

E=(Wm1²−2*dm1*Wm1+4hs/(λ*R)+dm1*Wm1)^{1/2} (7)

From the formulas (5), (6), and (7), for the width Wm2 and the depth dm2 of the second portion 12, following formulas (8) and (9) are obtained as the setting condition.

Wm2≥Wm1+2*hm2 (8)

dm2≥dm1+2*hm2 (9)

The formulas (8) and (9) are examples in which the setting condition is determined for the size of the second portion 12 based on the upper limit of the thermal resistance value of the heat conduction sheet 20. A case in which the setting condition is determined when the size of the heat conduction sheet 20 is determined will be described below.

The width Wm2 and the depth dm2 of the second portion 12 are equal to the width and the depth of the heat conduction sheet 20. Therefore, the height hm2 at which the heat diffusion region 200 spreads to a range of the width Wm2 and the depth dm2 can be determined as the setting condition. If the heat spreads to the second surface 122 by forming an angle θ, the width Wm2 and the depth dm2 are represented by following formulas (10) and (11).

Wm2=W1m+2*hm2*cos θ/sin θ (10)

dm2=d1m+2*hm2*cos θ/sin θ (11)

Therefore, as the setting condition, the height hm2 satisfies both of following formulas (12) and (13).

hm2≥(Wm2−Wm1)/2*sin θ/cos θ (12)

hm2≥(dm2−dm1)/2*sin θ/cos θ (13)

### Modified Example

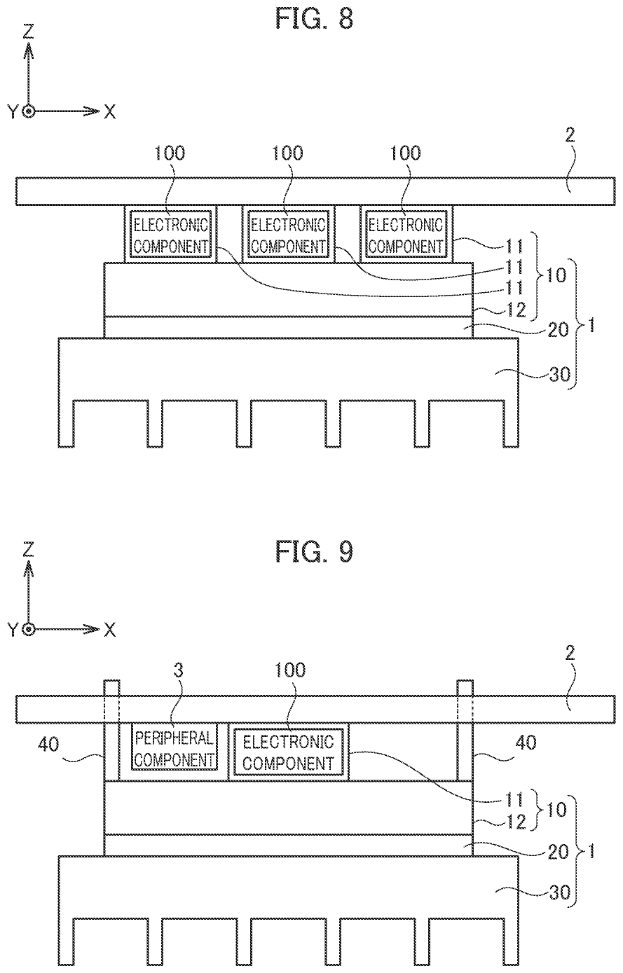

In the above, a case in which one electronic component 100 is mounted in the package 1 has been described. However, a plurality of electronic components 100 may be mounted in the package 1. In a package 1 according to a modified example of the first embodiment shown in FIG. 8, a plurality of first portions 11 are separated from each other and are connected to a second portion 12. The electronic component 100 is stored in each first portion 11.

According to the package 1 shown in FIG. 8, peripheral components 3 can be arranged between the first portions 11 in plain view and between the second portion 12 and a wiring substrate 2. This can shorten wiring connecting the plurality of electronic components 100 mounted in the package 1 and the peripheral components 3.

### Second Embodiment

FIG. 9 shows a package 1 according to a second embodiment. The package 1 shown in FIG. 9 further includes columns 40 arranged on a second portion 12 in a remaining part of a region in which a first portion 11 is arranged. The columns 40 extend in the direction normal to the surface through which the first portion 11 and the second portion 12 are connected. A part of each column 40 passes through a wiring substrate 2 and is fixed to the wiring substrate 2. Other configurations of the package 1 shown in FIG. 9 are the same as those of the first embodiment shown in FIG. 1.

Since the area of the second portion 12 is larger than that of the first portion 11, if the package 1 is connected to the wiring substrate 2 only by means of the first portion 11, distortion may occur in the second portion 12. If distortion occurs in the second portion 12, the electronic component 100 may become detached from the mounting region or broken. In particular, when the size of the electronic component 100 is small, the area of the second portion 12 relative to the area of the first portion 11 increases, and distortion is likely to occur in the second portion 12. For example, in the case of a semiconductor device having an electronic component 100 formed on a GaN substrate, the size of the first portion 11 is designed to be small in order to reduce parasitic inductance.

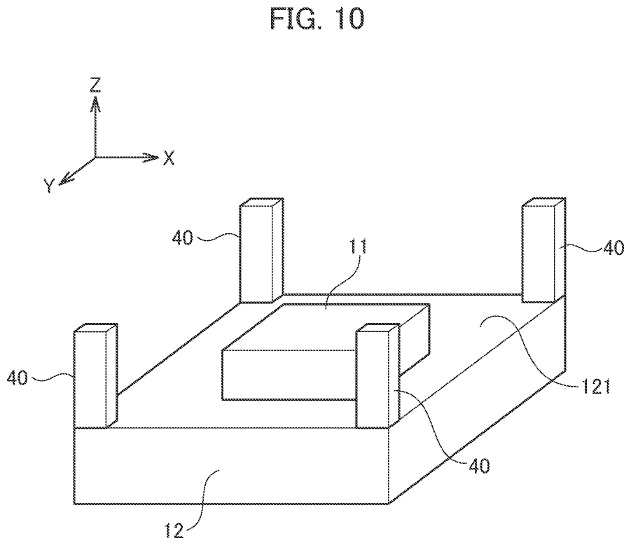

In the package 1 having the columns 40, as shown in FIG. 10, for example, four columns 40 are arranged in the outer edge regions of a first surface 121 of the second portion 12 so as to surround the vicinity of the first portion 11. Each column 40 has one end connected to the second portion 12 and the other end connected to a wiring substrate 2. Therefore, the package 1 having the columns 40 can suppress the occurrence of distortion in the second portion 12. As a result, it is possible to reduce detachment of the electronic component 100 from the mounting region and breakage of the electronic component 100 caused by distortion that has occurred in the second portion 12. The arrangement of the columns 40 shown in FIG. 10 is an example, and the positions or the number of columns 40 can be set as desired. Other configurations of the package 1 according to the second embodiment are substantially the same as those of the first embodiment, and therefore duplicate descriptions will be omitted.

### Other Embodiments

The present embodiment has been described as above, but the statements and drawings that form part of the disclosure should not be understood as limiting the present embodiment. Various alternative embodiments, examples, and operating techniques will be apparent to those skilled in the art from this disclosure.

For example, the package 1 having the heat conduction sheet 20 arranged between the mounting portion 10 and the heat sink 30 has been described above, but the package 1 may not have the heat conduction sheet 20 and the heat sink 30 may be arranged at the mounting portion 10.

Further, the above shows a case where a first portion 11 is arranged in the center of a first surface 121 of a second portion 12. However, the first portion 11 can be arranged at any position on the first surface 121 of the second portion 12. For example, the position of the first portion 11 relative to the position of the second portion 12 may be adjusted depending on the position or the like of a peripheral component 3 arranged on a wiring substrate 2.

In this way, the present embodiment includes various embodiments and the like that are not described herein.

### APPENDIXES

### Appendix 1

A package in which an electronic component can be mounted, including:
a first portion having defined therein a mounting region in which the electronic component is mounted; and
a second portion connected to the first portion, in which
an area of the second portion is larger than an area of the first portion in plain view viewed from a direction normal to a surface through which the first portion and the second portion are connected.

According to the package according to Appendix 1, it is possible to increase the heat radiation performance of the package in which the electronic component is mounted and to shorten the length of wiring connected to the electronic component, the wiring being arranged on a wiring substrate on which the package is incorporated.

### Appendix 2

The package according to Appendix 1, in which
the first portion includes a first plate and a second plate which are apart from and opposite from each other,
the mounting region is set on a surface of the second plate facing the first plate, and
the second plate is connected to the second portion.

### Appendix 3

The package according to Appendix 2, in which
the first portion includes a side plate that connects the first plate and the second plate, and
the electronic component arranged in the mounting region is in contact with the side plate.

### Appendix 4

The package according to any one of Appendixes 1 to 3, in which
both surfaces of the second portion are defined by a first surface connected to the first portion and a second surface facing the first surface, and
the first surface and the mounting region are thermally connected.

### Appendix 5

The package according to Appendix 4, in which
the first portion is arranged in the center of the first surface of the second portion.

### Appendix 6

The package according to any one of Appendixes 1 to 5, further including:
a heat sink facing the second portion.

### Appendix 7

The package according to Appendix 6, further including:
an insulating heat conduction sheet disposed between the second portion and the heat sink.

### Appendix 8

The package according to Appendix 7, in which
the first portion and the second portion have a parallelepiped shape, and
assuming that the first portion has a width Wm1 and a depth dm1, and the second portion has a width Wm2, a depth dm2, and a height hm2, relationships of formulas shown below are satisfied.

Wm2≥Wm1+2*hm2

dm2≥dm1+2*hm2

According to the package according to Appendix 8, the heat diffusion region is approximately the entire surface of the second surface, and high thermal conductivity can be achieved.

### Appendix 9

The package according to Appendix 7, in which
the first portion and the second portion have a parallelepiped shape,
assuming that the first portion has a width Wm1 and a depth dm1, and the second portion has a width Wm2, a depth dm2, and a height hm2, when heat is transferred from the first portion to the second portion by forming an angle θ with a surface of the second portion facing a surface connected to the first portion, relationships of formulas shown below are satisfied.

hm2≥(Wm2−Wm1)/2*sin θ/cos θ

hm2≥(dm2−dm1)/2*sin θ/cos θ

According to the package according to Appendix 9, the heat diffusion region is approximately the entire surface of the second surface, and high thermal conductivity can be achieved.

### Appendix 10

The package according to any one of Appendixes 1 to 9, in which
the first portion is provided in plurality, and the plurality of first portions are separated from each other and are connected to the second portion.

According to the package according to Appendix 10, it is possible to shorten wiring connecting the plurality of electronic components mounted in the package and peripheral components.

### Appendix 11

The package according to any one of Appendixes 1 to 10, which is configured to be able to be incorporated on a surface of a wiring substrate, the package further including:
a column that is disposed on the second portion in a remaining part of a region in which the first portion is disposed and extends in the direction normal to the surface, in which
the column has one end connected to the second portion and the other end connected to the wiring substrate facing the first portion.

According to the package according to Appendix 11, the occurrence of distortion in the second portion can be suppressed.

What is claimed is:

1. A package in which an electronic component can be mounted, comprising:
a first portion having defined therein a mounting region in which the electronic component is mounted; and
a second portion connected to the first portion, wherein
an area of the second portion is larger than an area of the first portion in plain view viewed from a direction normal to a surface through which the first portion and the second portion are connected.

2. The package according to claim 1, wherein
the first portion includes a first plate and a second plate which are apart from and opposite from each other,
the mounting region is set on a surface of the second plate facing the first plate, and
the second plate is connected to the second portion.

3. The package according to claim 2, wherein
the first portion includes a side plate that connects the first plate and the second plate, and
the electronic component arranged in the mounting region is in contact with the side plate.

4. The package according to claim 1, wherein
both surfaces of the second portion are defined by a first surface connected to the first portion and a second surface facing the first surface, and
the first surface and the mounting region are thermally connected.

5. The package according to claim 4, wherein
the first portion is arranged in the center of the first surface of the second portion.

6. The package according to claim 1, further comprising:
a heat sink facing the second portion.

7. The package according to claim 6, further comprising:
an insulating heat conduction sheet disposed between the second portion and the heat sink.

8. The package according to claim 7, wherein
the first portion and the second portion have a parallelepiped shape, and
assuming that the first portion has a width Wm1 and a depth dm1, and the second portion has a width Wm2, a depth dm2, and a height hm2, relationships of formulas shown below are satisfied,
Wm2≥Wm1+2*hm2
dm2≥dm1+2*hm2.

9. The package according to claim 7, wherein
the first portion and the second portion have a parallelepiped shape,
assuming that the first portion has a width Wm1 and a depth dm1, and the second portion has a width Wm2, a depth dm2, and a height hm2, when heat is transferred from the first portion to the second portion by forming an angle θ with a surface of the second portion facing a surface connected to the first portion, relationships of formulas shown below are satisfied,
hm2≥(Wm2−Wm1)/2*sin θ/cos θ
hm2≥(dm2−dm1)/2*sin θ/cos θ.

10. The package according to claim 1, wherein
the first portion is provided in plurality, and the plurality of first portions are separated from each other and are connected to the second portion.

11. The package according to claim 1, which is configured to be able to be incorporated on a surface of a wiring substrate, the package further comprising:
a column that is disposed on the second portion in a remaining part of a region in which the first portion is disposed, and extends in the direction normal to the surface, wherein
the column has one end connected to the second portion and the other end connected to the wiring substrate facing the first portion.
